(19) United States
(12) Patent Application Publication
(10) Pub. No.: US 2022/0285547 A1
(43) Pub. Date: Sep. 8, 2022

(54) METHOD OF MANUFACTURING SEMICONDUCTOR DEVICE AND SEMICONDUCTOR DEVICE

(71) Applicant: LAPIS Semiconductor Co., Ltd., Yokohama-shi (JP)

(72) Inventor: Tetsuya YAMAMOTO, Yokohama-shi (JP)

(73) Assignee: LAPIS Semiconductor Co., Ltd., Yokohama-shi (JP)

(21) Appl. No.: 17/687,812

(22) Filed: Mar. 7, 2022

(30) Foreign Application Priority Data
Mar. 8, 2021 (JP) 2021-035966

(51) Int. Cl. H01L 29/788; H01L 29/66

(52) U.S. Cl. CPC H01L 29/788; H01L 29/66825

(57) ABSTRACT

A method of manufacturing a semiconductor device including: forming a conductor film for floating gates through a gate insulating film on a semiconductor substrate; etching the conductor film, the gate insulating film, and the semiconductor substrate so as to form an element isolation trench extending in one direction of the semiconductor substrate and having a width and depth that periodically change along an extension direction; and forming an element isolation insulating film by burying the element isolation trench with an insulator.

### CROSS-REFERENCE TO RELATED APPLICATION

This application is based on and claims priority under 35 USC 119 from Japanese Patent Application No. 2021-035966 filed on Mar. 8, 2021, the disclosure of which is incorporated by reference herein.

### BACKGROUND

### Technical Field

The present disclosure relates to a method of manufacturing a semiconductor device and a semiconductor device, and in particular relates to a method of manufacturing a semiconductor device and a semiconductor device using silicon (Si).

### Related Art

A recent trend is an increase in Si semiconductor products that combine a shallow trench isolation (STI) process with patterning in a bit line (hereafter “BL”) direction of a floating gate in flash (non-volatile) memory.

A configuration disclosed in Japanese Patent Application Laid-Open (JP-A) No. 2013-187386 includes: a process of forming a protrusion extending along a first direction on a substrate; a process of forming a first film on the substrate so as to cover the protrusion; a process of forming plural first trenches in the first film that extend along a second direction intersecting the first direction, with the plural first trenches arranged parallel to each other at a larger pitch than a width of the first trenches; a process of burying a second film in the plural first trenches; a process of performing etching of the first film using the second film as a mask so as to form a second trench exposing portions of the substrate; and a process of burying a conductive material in the second trench.

A configuration disclosed in JP-A No. 2007-96339 includes: (a) a process of forming a first silicon oxide film on a semiconductor substrate; (b) a process of forming a first silicon nitride film on the first silicon oxide film; (c) a process performed after process (b) of selectively removing the first silicon nitride film and the first silicon oxide film so as to selectively expose the semiconductor substrate and erode the semiconductor substrate; (d) a process performed after process (c) of taking the first silicon oxide film back from an edge of the first silicon nitride film; (e) a process performed after process (d) of using a thermal oxidation method on the semiconductor substrate exposed at process (c) to form a second silicon oxide film with a film thickness thicker than the first silicon oxide film and to form a bird's beak on the second silicon oxide film in a region where the first silicon oxide film has been taken back; (f) a process of forming a sloping face on the semiconductor substrate by a process of removing the second silicon oxide film; (g) a process performed after process (f) of forming a trench in the semiconductor substrate by etching the semiconductor substrate; (h) a process performed after process (g) of forming a third silicon oxide film in an inner wall of a trench using a thermal oxidation method; and (i) a process of depositing a fourth silicon oxide film on the third silicon oxide film and on the first silicon nitride film inside the trench.

Specific explanation follows regarding a method of manufacturing a floating gate in a Si semiconductor product, with reference to a method of manufacturing a semiconductor device (flash memory) according to a comparative example showed in FIG. 7A to FIG. 7G. FIG. 7A to FIG. 7G show a manufacturing method of an element isolation insulating film for isolating memory cell elements of a semiconductor device, and layer portions peripheral thereto. Note that the “BL direction” mentioned above is a direction indicated by D1 in FIG. 7G, and is the same direction as an extension direction of the element isolation insulating film.

First, a floating gate coupling oxide film (hereafter referred to as a “FG coupling oxide film”) 109 that will become an insulating film adjacent to a floating gate is formed on a Si semiconductor substrate 120 by oxidation processing, and a floating gate polysilicon film (hereafter referred to as a “FG polysilicon film”) 108 that will become a floating gate is formed on the FG coupling oxide film 109. Then a silicon nitride film (SiN film) 123 that will become a mask employed when etching a trench (groove) 124 is formed on the FG polysilicon film 108 using chemical vapor deposition (CVD) processing (FIG. 7A). Then the trench 124 is formed and patterning of the floating gate is performed using lithographic and etching technologies (FIG. 7B).

Then in order to suppress crystal defects occurring from STI process processing, a liner oxide film 125 is formed inside the trench 124 using heat treatment (FIG. 7C). Next, the inside of the trench 124 is buried in a non-doped silicate glass (NSG) film 126 using CVD processing (FIG. 7D), and the NSG film 126 is polished to a position higher than the FG polysilicon film 108 using chemical mechanical polishing (CMP) processing (FIG. 7E).

Next the NSG film 126 serving as an element isolation insulating film is formed by removing the SiN film 123 and patterning in a BL direction D1 of the floating gate (FIG. 7F, FIG. 7G, wherein FIG. 7G is a perspective view of FIG. 7F). Then word lines, source lines, and bit contacts, described later, are formed using lithographic processing, etching processing, and heat treatment, so as to manufacture a semiconductor device mounted with memory cell elements.

Explanation follows regarding problems with the method of manufacturing a floating gate in the method of manufacturing a semiconductor device according to the above comparative example, with reference to FIG. 8A, FIG. 8B, FIG. 9, FIG. 10A, and FIG. 10B. FIG. 8A is a view showing a SiN film 123 that will become a mask when etching a trench 124, as viewed from the above direction of FIG. 7B. FIG. 8B is a cross-sectional view at a position of line a-a shown in FIG. 8A.

As shown in FIG. 8A, in cases in which the SiN film 123 having a rectangular shape extending in one direction is employed as a mask when etching the trench 124, the trench 124 with a constant depth and a constant width is formed along the BL direction D1, as shown in FIG. 8B. In a NSG film buried in such a trench 124, sometimes crystal defects occur due to film stress between selected bit lines and unselected bit lines, and between selected source lines and unselected source lines, which sometimes induces writing to fail, and malfunctioning of memory cell elements to occur.

Specifically, as shown in FIG. 9 for example, explanation follows using a case in which crystal defects have occurred between a selected bit line and an unselected bit line in a flash memory that applies a voltage of 0.3 V to bit lines of cells to be written, and applies a voltage of 2.5V to bit lines of write-protect cells. As shown in FIG. 10A, in cases in which a crystal defect has occurred between a selected bit line (selected BL) and an unselected bit line (unselected BL), the voltage of the unselected bit line sometimes drops below 2.5V due to the influence of the 0.3V applied to the selected bit line, which might result in miss-writing to the cell of the unselected bit line. Similarly, in cases in which a crystal defect has occurred between a selected source line and an unselected source line, the voltage of the unselected source line sometimes drops below the predetermined voltage, which might result in miss-writing to the cell of the unselected source line.

In order to prevent writing problems due to crystal defects as described above, a conceivable approach is to make the depth of the trench 124 deeper and to form a taper angle on the trench 124 when etching the trench 124, as shown in FIG. 10B. However, film stress is further increased in the NSG film 126 serving as the element isolation insulating film when the depth of the trench 124 is simply made deeper, and crystal defects still sometimes occur. Moreover, there is a need to find the optimal conditions in cases in which a taper angle is formed on the trench 124, which sometimes results on a longer development time.

### SUMMARY

The present disclosure was conceived in view of the above-described circumstances, and it is an object to provide a method of manufacturing a semiconductor device and semiconductor device capable of forming an element isolation insulating film in memory cells while suppressing crystal defects from occurring.

A method of manufacturing a semiconductor device according to the present disclosure includes forming a conductor film for floating gates through a gate insulating film on a semiconductor substrate, etching the conductor film, the gate insulating film, and the semiconductor substrate so as to form an element isolation trench extending in one direction of the semiconductor substrate and having a width and depth that periodically change along an extension direction, and forming an element isolation insulating film by burying the element isolation trench with an insulator.

A method of manufacturing a semiconductor device according to the another present disclosure includes forming a conductor film for floating gates through a gate insulating film on a semiconductor substrate, etching the conductor film, the gate insulating film, and the semiconductor substrate so as to form an element isolation trench, forming a first liner film using chemical vapor deposition so as to cover a surface of the element isolation trench including side faces of the etched conductor film, removing the first liner film by etching a part of the element isolation trench in an extension direction using a mask, oxidizing the surface of the element isolation trench to form a second liner film, and burying the element isolation trench with an insulator, and forming an element isolation insulating film so as to extend in one direction of the semiconductor substrate and to have a width and depth that periodically change along the extension direction.

A semiconductor device according to the present disclosure includes a semiconductor substrate, an element isolation insulating film configured by depositing an insulator in an element isolation trench provided at the semiconductor substrate, the element isolation insulating film extending in one direction of the semiconductor substrate and having a width and depth that periodically change along an extension direction, a gate insulating film provided on a main face of the semiconductor substrate so as to contact the element isolation insulating film, a floating gate provided on the gate insulating film so as to contact the element isolation insulating film, a source line including a source region formed at the main face and a source wiring-line connected to the source region and arranged adjacent to the floating gate, a bit contact including a drain region formed at the main face and a contact portion connected to the drain region, and a word line including a control gate provided on an insulating film and adjacent to the floating gate through the insulating film formed on the semiconductor substrate.

According to the present disclosure, it is possible to provide a method of manufacturing a semiconductor device and a semiconductor device capable of forming an element isolation insulating film in memory cells while suppressing crystal defects from occurring.

### BRIEF DESCRIPTION OF THE DRAWINGS

Exemplary embodiments of the present disclosure will be described in detail based on the following figures, wherein:

FIG. 1 is a cross-sectional view showing an example of a configuration of a semiconductor device according to a first exemplary embodiment;

FIG. 2 is a perspective view showing an example of a configuration of a semiconductor device according to the first exemplary embodiment;

FIG. 3A to FIG. 3G are diagrams showing an example of a method of manufacturing a semiconductor device according to the first exemplary embodiment;

FIG. 4A is a plan view showing an example of a mask employed in etching processing in a method of a manufacturing a semiconductor device according to the first exemplary embodiment;

FIG. 4B is a cross-sectional view at a position of line b-b shown in FIG. 4A;

FIG. 4C is a cross-sectional view at a position of line c-c shown in FIG. 4A;

FIG. 5A to FIG. 5C are diagrams showing an example of a method of manufacturing a semiconductor device according to a second exemplary embodiment;

FIG. 6D-1 to FIG. 6G-1 and FIG. 6D-2 to FIG. 6G-2 are cross-sectional views showing an example of a method of manufacturing a semiconductor device according to the second exemplary embodiment;

FIG. 7A to FIG. 7G are diagrams showing a method of manufacturing a semiconductor device according to a comparative example;

FIG. 8A is a plan view showing a mask employed in etching processing in a method of manufacturing a semiconductor device according to the comparative example;

FIG. 8B is a cross-sectional view at a position of line a-a shown in FIG. 8A;

FIG. 9 is a diagram to explain problems with the method of manufacturing a semiconductor device according to the comparative example; and

FIG. 10A and FIG. 10B are diagrams to explain problems with the method of manufacturing a semiconductor device according to the comparative example.

### DETAILED DESCRIPTION

Hereinafter, exemplary embodiments of the present disclosure will be described in detail with reference to the drawings. The following explanation will describe an example of a mode in which a semiconductor device according to the present disclosure is applied to flash memory (non-volatile memory).

(First Exemplary Embodiment)

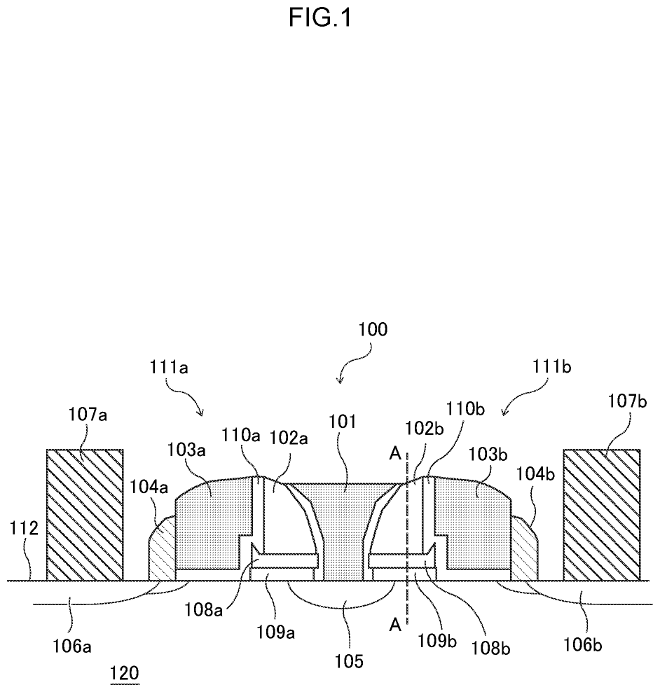

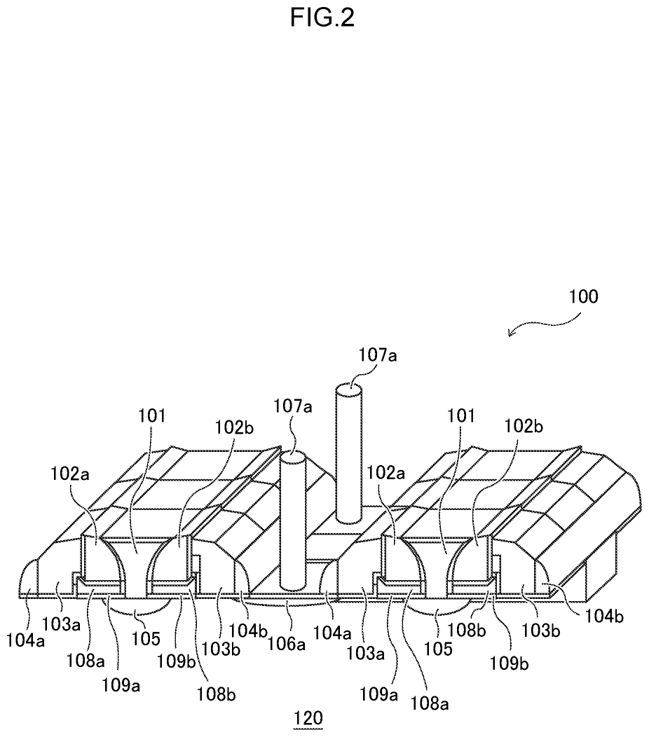

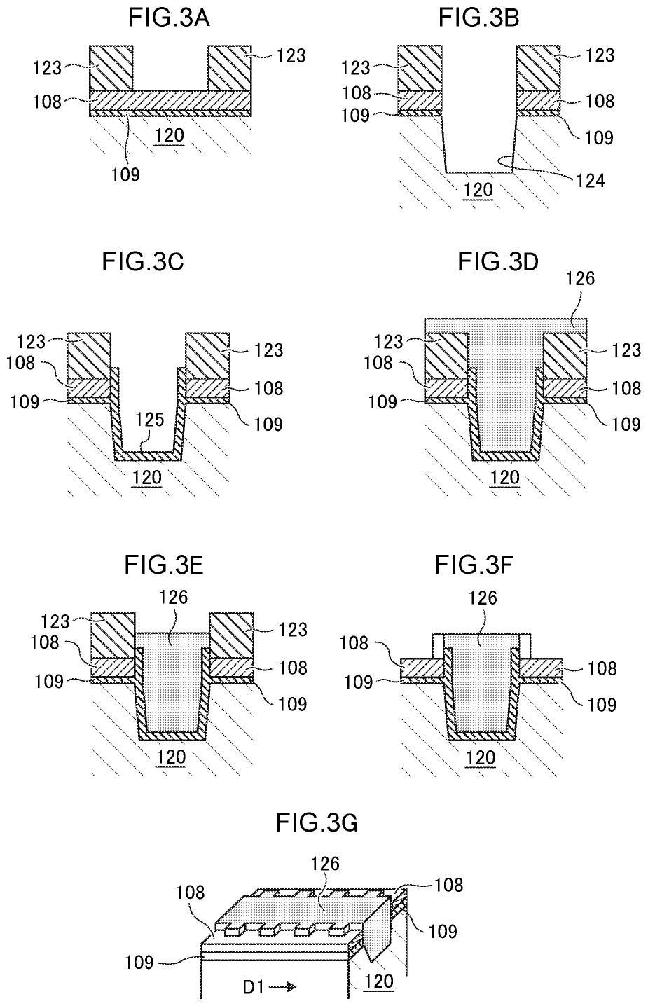

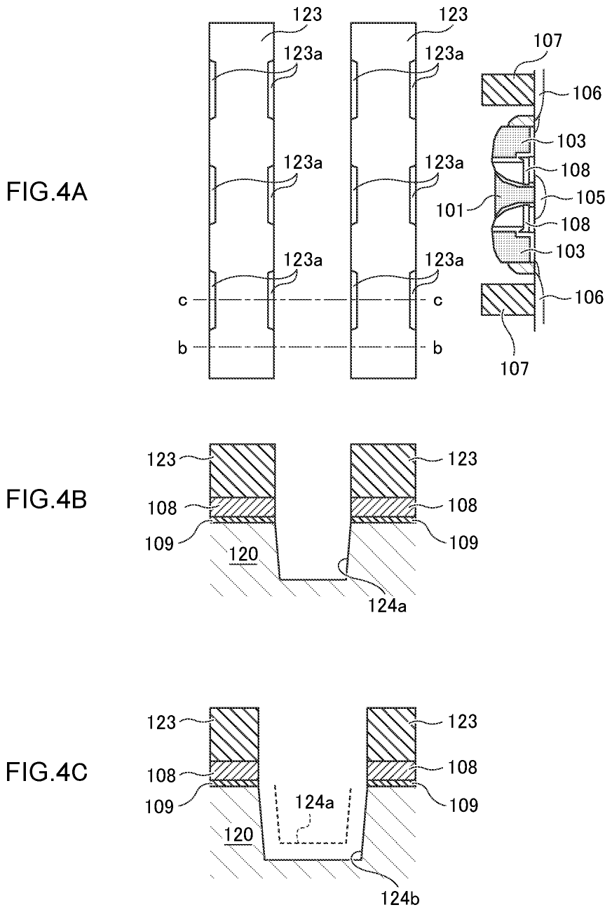

Explanation follows regarding a method of manufacturing a semiconductor device and a semiconductor device according to the present exemplary embodiment, with reference to FIG. 1, FIG. 2, FIG. 3A to FIG. 3G, and FIG. 4A to FIG. 4C. FIG. 1 is a cross-sectional view showing an example of a configuration of a semiconductor device 100 according to the present exemplary embodiment, and FIG. 2 is a perspective view showing an example of a configuration of the semiconductor device 100 according to the present exemplary embodiment.

As shown in FIG. 1 and FIG. 2, the semiconductor device 100 includes plural memory cell array in which two split-gate memory cells 111a, 111b that share a source region 105 and a source wiring-line 101 are arranged with plane symmetry facing each other across the source region 105 and the source wiring-line 101. The memory cell 111a and the memory cell 111b are configured similarly to each other except in that they have different orientations, and so the memory cell 111a will be explained as an example below.

The memory cell 111a formed on a main face 112 of a semiconductor substrate 120 is configured including the source region 105, the source wiring-line 101, an FG coupling oxide film 109a serving as a gate insulating film, an FG polysilicon film 108a, which is a conductor film that serving as a floating gate, a spacer 102a, a control gate 103a, a side wall 104a, a drain region 106a, and a contact portion 107a. The semiconductor substrate 120 employs, for example, an Si substrate.

The source region 105 is formed by diffusing an impurity into the semiconductor substrate 120. The source wiring-line 101 is connected to the source region 105, configuring a source line of the semiconductor device 100. The FG polysilicon film 108a is provided on the FG coupling oxide film 109a formed on the semiconductor substrate 120. The spacer 102a is formed on the FG polysilicon film 108a.

The control gate 103a is formed on the semiconductor substrate 120 through a tunnel insulating film 110a, and configures a word line. The control gate 103a is arranged so as to be adjacent to the FG coupling oxide film 109a, the FG polysilicon film 108a, and the spacer 102a through the tunnel insulating film 110a. The side wall 104a is formed adjacent to the control gate 103 a. The drain region 106a is formed by diffusing an impurity into the semiconductor substrate 120. A bit contact is configured by the contact portions 107a connected to the drain region 106a and the drain region 106a.

Writing is performed in the semiconductor device 100 configured as described above by channel hot-electrons generated in the semiconductor substrate 120 being injected into the FG polysilicon film 108a. Moreover, data erasure is performed by withdrawing electrons from the FG polysilicon film 108a into the control gate 103a through the tunnel insulating film 110a. Furthermore, the state (ON, OFF) of the memory cell 111a is detected by applying a read voltage to the control gate 103a.

Next, detailed explanation follows regarding processes in a manufacturing method of the semiconductor device 100 according to the present exemplary embodiment, with reference to FIG. 3A to FIG. 3G. FIG. 3A to FIG. 3G show a method of forming an element isolation insulating film for isolating memory cell elements on the semiconductor device 100. FIG. 3A to FIG. 3F are cross-sectional view at a position of line A-A of semiconductor device 100 shown in FIG. 1, FIG. 3G is a perspective view of FIG. 3F as viewed from a BL direction D1 side.

First, the FG coupling oxide film 109 that will become the gate insulating film adjacent to the floating gate is formed on the semiconductor substrate 120 using oxidation processing, and then the FG polysilicon film 108 that will become a conductor film that serving as a floating gate is formed thereon. Namely, the FG polysilicon film 108 is formed on the semiconductor substrate 120 through the FG coupling oxide film 109. Next, the SiN film 123 that will become a mask when etching the trench 124 serving as an element isolation trench is formed by chemical vapor deposition (CVD) processing (FIG. 3A). Then lithographic and etching processing are employed to etch the FG polysilicon film 108, the FG coupling oxide film 109, and the semiconductor substrate 120, and the trench 124 serving as the element isolation trench is formed and floating gate patterning performed (FIG. 3B, TR etching process).

When this is being performed, as a trench pattern of the mask employed when etching the trench 124 is a pattern that extends in the BL direction D1 and has a width indented by including periodic indentations 123a, as shown in FIG. 4A. Namely, a mask is employed that extends along one direction and has a width changing periodically along the extension direction. In other words, the extension direction of the mask is formed with a wavy shape.

FIG. 4B is a cross-sectional view at a position of line b-b shown in FIG. 4A, and FIG. 4C is a cross-sectional view at a position of line c-c shown in FIG. 4A. As shown in FIG. 4B and FIG. 4C, a width of a trench 124b formed at a region where indentations 123a of the SiN film 123, as a mask, are disposed is formed wider than a width of a trench 124a formed at a region where the indentations 123a are not disposed. The depth of the trench 124b formed at a region where the indentations 123a of the SiN film 123 are disposed is formed deeper than the depth of the trench 124a formed at a region where the indentations 123a are not disposed. Namely, an etched region (etching surface area) is wider in the width direction at a region where a width of the SiN film 123 is narrow, and the trench formed thereby is deeper than the trench formed at a region where the width of the SiN film 123 is wider. Moreover, the etching rates differ in wider width regions and narrow width regions of the SiN film 123. Namely, by using the mask with the wavy shape as described above, the trench 124 is configured so as to have contiguous and alternately repeating trenches 124a and trenches 124b, with the width and the depth formed with alternating protrusions and indentations in a wavy shape along the extension direction.

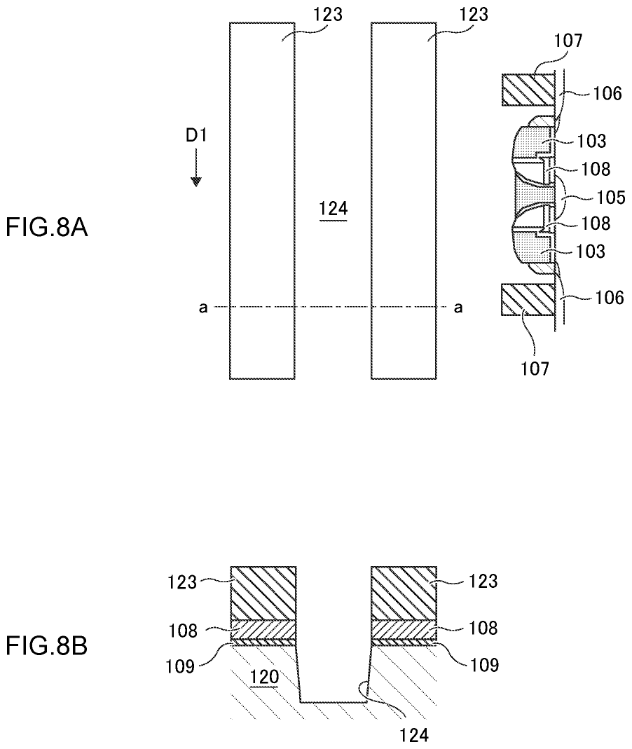

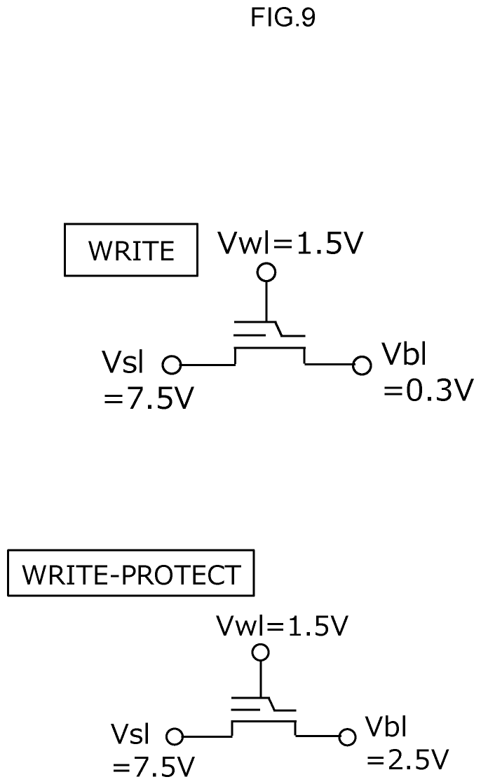

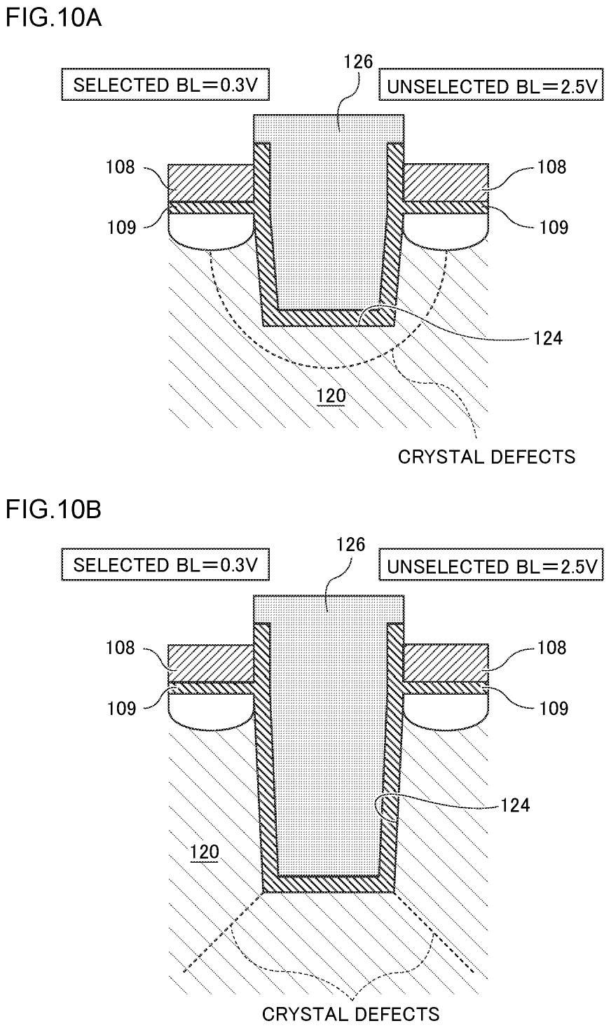

Namely, a mask employed has a profile as shown in FIG. 4A extending in one direction with a width that changes by periodically indenting, and etching is performed therewith so as to form a trench 124 that extends in one direction of the semiconductor substrate 120 and has a width and depth that periodically changes along the extension direction, as shown in FIG. 4B and FIG. 4C. Thus, in comparison to cases in which a trench pattern employed is as shown in FIG. 8A, crystal defects are suppressed from occurring, and film stress is relieved in an element isolation insulating film formed by burying the trench 124 with an insulator, as described later.

Moreover, as shown in FIG. 4A, the indentations 123a of the SiN film 123 are, for example, etched so as to be disposed at positions corresponding to regions where the source wiring-line 101 connected to the source region 105 is formed at a main face of the semiconductor substrate 120 and to regions where the contact portion 107 connected to a drain region 106 is formed at a main face of the semiconductor substrate 120. This thereby enables the element isolation insulating film to be formed with a wider width and a deeper depth at regions where the source lines are disposed and at regions where the bit contacts are disposed.

Namely, the trench 124 that will become the element isolation trench is configured so as to have a region with a wider width and deeper depth than other regions, which are arranged at a region where the source wiring-line 101 connected to the source region 105 is formed at the main face of the semiconductor substrate 120 and at a region where the contact portion 107 connected to a drain region 106 is formed at the main face.

Namely, the SiN film 123 having a profile as described above, in which the width periodically changes along the extension direction, is employed to erode the semiconductor substrate 120 at field regions using etching processing, and the trench 124 is formed extending along one direction of the semiconductor substrate 120, and with a profile having a width and depth that periodically change along the extension direction.

Next thermal oxidation is performed, oxidizing the surface of the trench 124, including the side faces of the FG coupling oxide film 109, the FG polysilicon film 108, and the SiN film 123, and forming the liner oxide film 125 (FIG. 3C, liner oxide process).

Next, NSG serving as an insulating material is deposited in the trench 124 using CVD processing, the trench 124 is buried with the NSG, and an NSG film 126 is formed as the element isolation insulating film (FIG. 3D, STI buried NSG process). Then the NSG film 126 is polished to a higher position than the FG polysilicon film 108 using CMP processing (FIG. 3E, TR-CMP process).

Next, the SiN film 123 on the FG polysilicon film 108 is removed (FIG. 3F, TR-SiN removal process). Patterning in the BL direction D1 of the floating gate is performed by this process. As shown in FIG. 3G, the NSG film 126 is formed as an element isolation insulating film that extends in the BL direction D1 of the semiconductor substrate 120 and has a width and depth that periodically change along the extension direction. This is followed by lithographic processing, etching processing, and heat treatment so as to form word lines, source lines, and bit contacts (not shown in the drawings), thereby manufacturing the semiconductor device 100 according to the present exemplary embodiment mounted with plural memory cells 111.

In the method of manufacturing the semiconductor device and the semiconductor device according to the present exemplary embodiment, the film stress of the NSG film 126 serving as the element isolation insulating film buried in the trench 124 is reduced by etching such that the width and depth of the trench 124 serving as the element isolation trench periodically changes along the extension direction, enabling crystal defects to be suppressed from occurring. This enables element isolation to be achieved in memory cells while suppressing crystal defects from occurring. Namely, this enables miss-writing caused by crystal defects to be suppressed.

(Second Exemplary Embodiment)

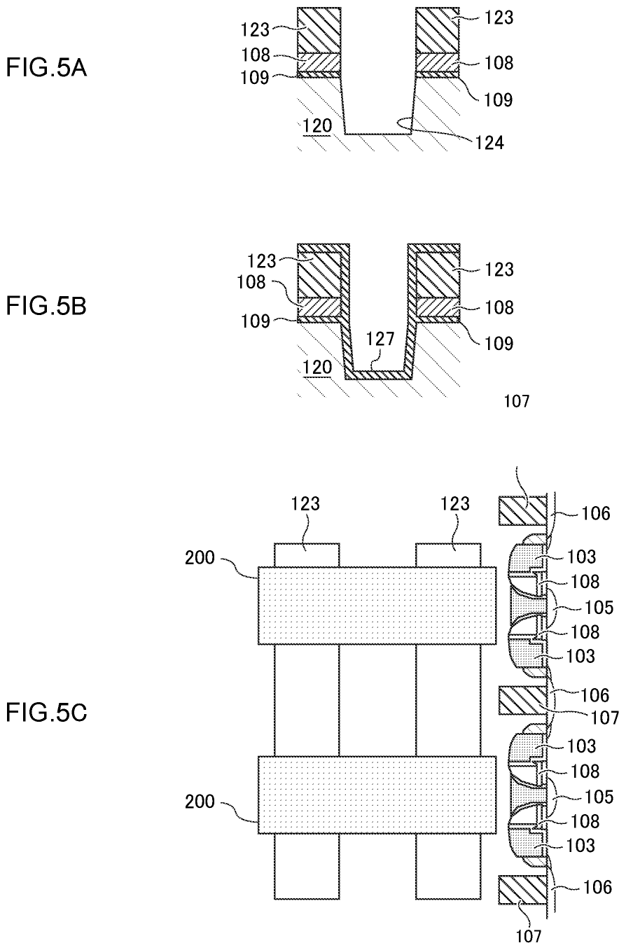

Explanation follows regarding a method of manufacturing a semiconductor device and a semiconductor device according to the present exemplary embodiment, with reference to FIG. 5A to FIG. 5C, FIG. 6D-1 to FIG. 6G-1 and FIG. 6D-2 to FIG. 6G-2. The present exemplary embodiment is the exemplary embodiment described above, with a modified method for forming the element isolation insulating film.

In the manufacturing method according to the present exemplary embodiment, a liner NSG film is formed prior to forming a liner oxide film 125 when forming an STI pattern, then the liner oxide film 125 is formed after locally removing the liner NSG film using a GST mask, and the width and depth of the trench 124 serving as the element isolation trench are formed so as to periodically change.

First, a FG coupling oxide film 109 that will become the gate insulating film adjacent to a floating gate is formed on a semiconductor substrate 120 using oxidation processing, and then a FG polysilicon film 108, which is a conductor film that serving as a floating gate is formed thereon. Namely, the FG polysilicon film 108 is formed on the semiconductor substrate 120 through the FG coupling oxide film 109. Next, as a mask when etching the trench 124 that will become the element isolation trench, a SiN film 123 having a rectangular shape extending in a BL direction D1 is formed by chemical vapor deposition (CVD) processing. Then the FG polysilicon film 108, the FG coupling oxide film 109, and the semiconductor substrate 120 are etched using lithographic and etching processing, forming the trench 124 serving as the element isolation trench (FIG. 5A, TR etching process).

Next a liner NSG film 127 is formed as a first liner film by covering surfaces of the trench 124 including side faces of the SiN film 123, the FG polysilicon film 108, the FG coupling oxide film 109 using CVD processing (FIG. 5B, liner CVD process). Then part of the liner NSG film 127 is removed in the extension direction of the trench 124 using lithographic and wet etching processing employing a GST mask 200 such as that shown in FIG. 5C. Namely, the GST mask 200 is disposed periodically along the extension direction of the trench 124, and the liner NSG film 127 formed inside the trench 124 is removed periodically along the extension direction.

FIG. 6D-1 to FIG. 6G-1 are diagrams showing a manner in which an NSG serving as an insulator is deposited in the trench 124 at a region where the GST mask 200 is disposed as shown in FIG. 5C. FIG. 6D-2 to FIG. 6G-2 are diagrams showing a manner in which the NSG serving as the insulator is deposited in the trench 124 at a region where the GST mask 200 is not disposed as shown in FIG. 5C.

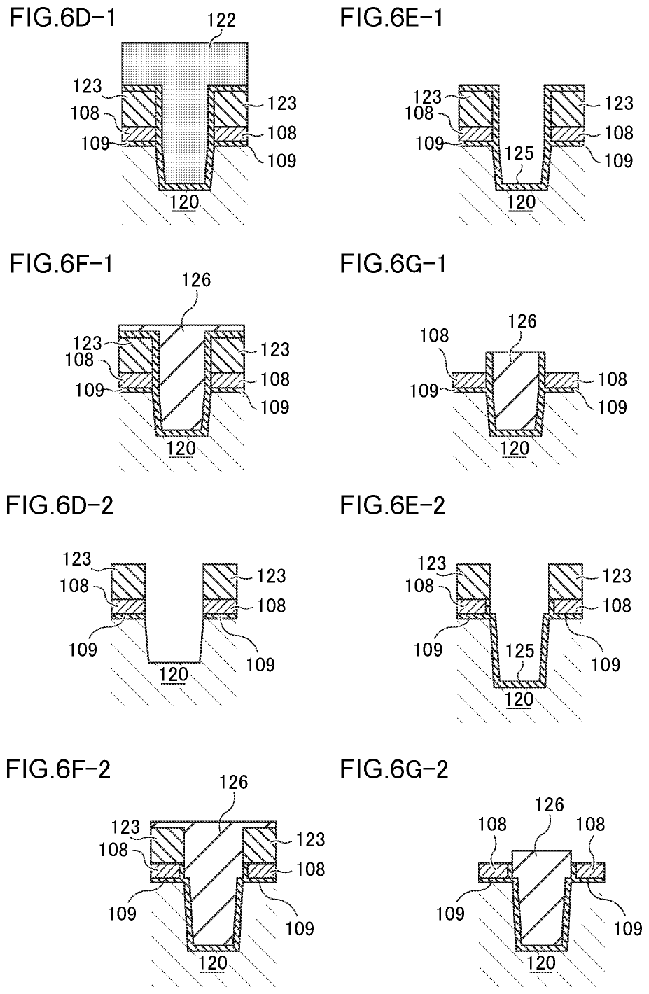

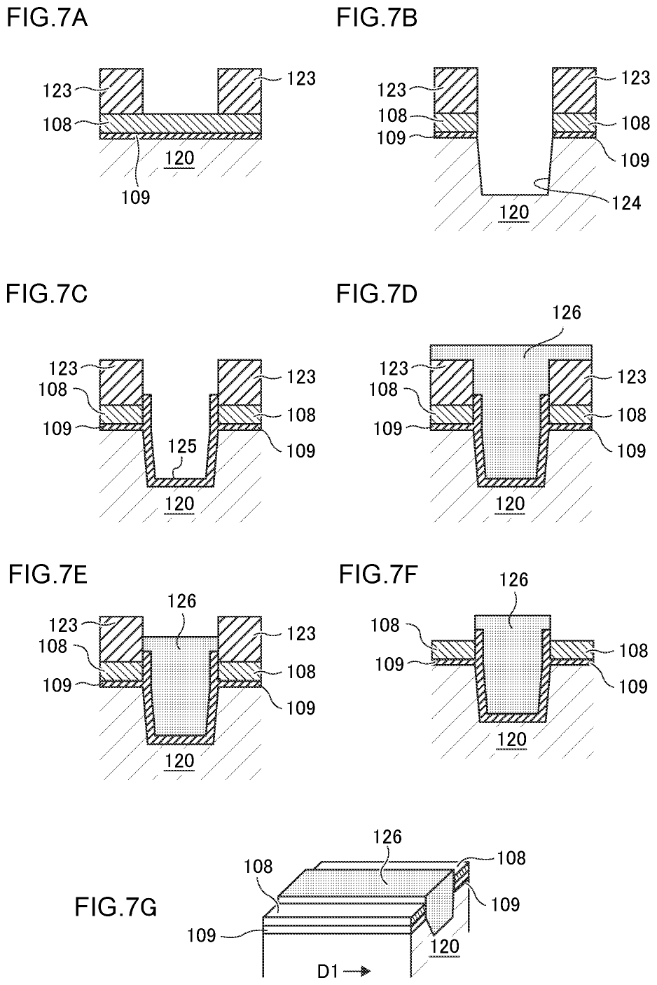

Namely, a resist 122 is formed on the liner NSG film 127 in the trench 124 at a region where the GST mask 200 is disposed, and the liner NSG film 127 is removed at a region where the GST mask 200 is not disposed (FIG. 6D-1, FIG. 6D-2, wet etching process). Namely, the liner NSG film 127 in the trench 124 is removed locally.

The resist 122 is then removed at regions where the GST mask 200 is disposed. Then in order to suppress crystal defects from occurring, the liner oxide film 125 is formed as a second liner film by oxidizing the surface of the trench 124 using heat treatment (FIG. 6E-1, FIG. 6E-2, liner oxidation process). When this is being performed, the surface of the FG polysilicon film 108 is also oxidized, as shown in FIG. 6E-2, at the regions where the liner NSG film 127 has been removed, which are the regions where the GST mask 200 was not disposed. Namely, the width of the trench 124 at the regions where the GST mask 200 is not disposed is formed wider than the width of the trench 124 at the region where the GST mask 200 is disposed, and the depth of the trench 124 at the regions where the GST mask 200 is not disposed is formed deeper than the depth of the trench 124 at the region where the GST mask 200 is disposed. Namely, regions where the GST mask 200 is not disposed are regions etched wider in the width direction, and are formed deeper than the depth of the trench 124 formed in regions where the GST mask 200 is disposed, such as shown in FIG. 6E-1. Namely, the width and depth of the trench 124 are formed in a wavy shape including alternating protrusions and indentations. Crystal defects are thereby suppressed from occurring compared to cases in which the trench pattern showed in FIG. 8A is employed, and film stress is relieved in the element isolation insulating film formed by burying the trench 124 with an insulator, as described later.

NSG is then deposited as an insulator in each of the trenches 124 using CVD processing, and the NSG film 126 that will become the element isolation insulating film is formed by burying the trench 124 with the NSG (FIG. 6F-1, FIG. 6F-2, STI burying NSG process). Namely, the NSG film 126 serving as the element isolation insulating film is formed extending in the BL direction D1 of the semiconductor substrate 120 and with a width and depth that periodically change along the extension direction. The NSG film 126 is polished to a higher position than the FG polysilicon film 108 using CMP processing.

Next the SiN film 123 on the FG polysilicon film 108 is removed (FIG. 6G-1, FIG. 6G-2, TR-SiN removal process). Patterning is performed in the BL direction D1 of the floating gate by the present process. Subsequent lithographic processing, etching processing, and heat treatment are performed so as to form word lines, source lines, and bit contacts, thereby manufacturing the semiconductor device 100 according to the present exemplary embodiment mounted with plural memory cells 111.

In the method of manufacturing the semiconductor device and the semiconductor device according to the present exemplary embodiment, the trench 124 is formed as the element isolation trench, and the liner NSG film is then formed prior to performing the liner oxidation process. Then after removing the liner NSG film periodically where the GST mask is disposed periodically in the extension direction, the liner oxide film is formed such that the width and depth of the NSG film that will become the element isolation insulating film periodically changes between the regions where the GST mask was disposed and the regions where the GST mask was not disposed, such that the element isolation insulating film is formed with a wavy shape including alternating protrusions and indentations. The film stress of the element isolation insulating film is thereby reduced, enabling crystal defects to be suppressed from occurring. This thereby enables element isolation to be performed in the memory cells while suppressing crystal defects from occurring. Namely, miss-writing caused by crystal defects is able to be suppressed from occurring.

Note that the semiconductor device manufacturing methods according to the exemplary embodiments of the present disclosure described above are merely examples thereof, and omission, addition, modification of processes, changes to the materials employed, and the like may all be implemented within a scope not departing from the spirit of the present disclosure.

What is claimed is:

1. A method of manufacturing a semiconductor device comprising:
forming a conductor film for floating gates through a gate insulating film on a semiconductor substrate;
etching the conductor film, the gate insulating film, and the semiconductor substrate so as to form an element isolation trench extending in one direction of the semiconductor substrate and having a width and depth that periodically change along an extension direction; and
forming an element isolation insulating film by burying the element isolation trench with an insulator.

2. The method of manufacturing a semiconductor device according to claim 1, wherein the element isolation trench is formed by using a mask having a width that periodically changes along the extension direction.

3. The method of manufacturing a semiconductor device according to claim 2, wherein the mask is a silicon nitride film.

4. The method of manufacturing a semiconductor device according to claim 1, wherein the element isolation trench includes regions of wider width and deeper depth than other regions, which are arranged at a region where a source line connected to a source region formed in a main face of the semiconductor substrate is formed and at a region where a bit contact connected to a drain region formed in the main face is formed.

5. The method of manufacturing a semiconductor device according to claim 1, further comprising oxidizing a surface of the element isolation trench including side faces of the etched conductor film so as to form a liner film.

6. A method of manufacturing a semiconductor device comprising:
forming a conductor film for floating gates through a gate insulating film on a semiconductor substrate;
etching the conductor film, the gate insulating film, and the semiconductor substrate so as to form an element isolation trench;
forming a first liner film using chemical vapor deposition so as to cover a surface of the element isolation trench including side faces of the etched conductor film;
removing the first liner film by etching a part of the element isolation trench in an extension direction using a mask;
oxidizing the surface of the element isolation trench to form a second liner film; and
burying the element isolation trench with an insulator, and forming an element isolation insulating film so as to extend in one direction of the semiconductor substrate and to have a width and depth that periodically change along the extension direction.

7. A semiconductor device comprising:
a semiconductor substrate;
an element isolation insulating film configured by depositing an insulator in an element isolation trench provided at the semiconductor substrate, the element isolation insulating film extending in one direction of the semiconductor substrate and having a width and depth that periodically change along an extension direction;
a gate insulating film provided on a main face of the semiconductor substrate so as to contact the element isolation insulating film;
a floating gate provided on the gate insulating film so as to contact the element isolation insulating film;
a source line including a source region formed at the main face and a source wiring-line connected to the source region and arranged adjacent to the floating gate;
a bit contact including a drain region formed at the main face and a contact portion connected to the drain region; and
a word line including a control gate provided on an insulating film and adjacent to the floating gate through the insulating film formed on the semiconductor substrate.

8. The semiconductor device according to claim 7, wherein the element isolation insulating film is configured so as to have a region, with a wider width and deeper depth than other regions, arranged at a region where the bit contact is disposed.

9. The semiconductor device according to claim 7, wherein the element isolation insulating film is configured so as to have a region, with a wider width and deeper depth than other regions, arranged at a region where the source line is disposed.
